(19) United States
(12) Patent Application Publication
(10) Pub. No.: US 2026/0235654 A1
(43) Pub. Date: Aug. 13, 2026

(54) JITTER MEASUREMENT CIRCUIT AND METHOD OF MEASURING JITTER PERFORMED BY THE SAME

(71) Applicant: Samsung Electronics Co., Ltd., Suwon-si (KR)

(72) Inventors: Daihyun Lim, Suwon-si (KR); Jaehyouk Choi, Seoul (KR); Junseok Lee, Seoul (KR); Suneui Park, Suwon-si (KR); Seungjun Bae, Suwon-si (KR)

(73) Assignee: SEOUL NATIONAL UNIVERSITY R&DB FOUNDATION, Seoul (KR)

(21) Appl. No.: 19/364,595

(22) Filed: Oct. 21, 2025

(30) Foreign Application Priority Data
Feb. 13, 2025 (KR) 10-2025-0018778

(51) Int. Cl. G01R 29/26; H03K 5/135

(52) U.S. Cl. CPC G01R 29/26; H03K 5/135

(57) ABSTRACT

An example jitter measurement circuit includes a first delay circuit, a time-to-digital converter, and a resolution circuit. The first delay circuit, based on a first clock signal, outputs a second clock signal. The time-to-digital converter includes a plurality of first delay cells delaying the first clock signal, a plurality of second delay cells delaying the second clock signal, and a plurality of first phase detectors, and outputs a plurality of first phase detection signals based on the first clock signal, the second clock signal, and a control signal. The resolution circuit outputs the control signal, determines a resolution of the time-to-digital converter as a first resolution based on the plurality of first phase detection signals, and outputs a result signal corresponding to a level of a jitter of the first clock signal. The resolution of the time-to-digital converter is adaptively changing depending on the level of the jitter.

### CROSS-REFERENCE TO RELATED APPLICATION

This application claims priority under 35 USC § 119 to Korean Patent Application No. 10-2025-0018778 filed on Feb. 13, 2025 in the Korean Intellectual Property Office (KIPO), the contents of which are herein incorporated by reference in their entirety.

### BACKGROUND

A digital circuit may operate in synchronization with a clock signal. For example, the digital circuit may include a plurality of flip-flops, and each of the flip-flops may operate in response to an edge of a clock signal. In addition, function blocks which are included in the digital circuit and operate in synchronization with a clock signal may have different operating frequencies, and thus, a plurality of clock signals having various frequencies may be generated.

A clock signal may have a jitter, and the performance of a function block may be degraded by the jitter of the clock signal. The jitter of the clock signal may differ between dies (or, chips) due to variations in a semiconductor manufacturing process, may vary depending on operating temperature of a digital circuit or a voltage applied to the digital circuit, and may depend on the performance of a circuit (e.g., a phase locked loop (PLL)) generating the clock signal.

### SUMMARY

The present disclosure relates to a jitter measurement circuit capable of efficiently measuring a jitter based on a resolution adaptively changing depending on a level of the jitter, and a method of measuring the jitter performed by the jitter measurement circuit.

In some implementations, a jitter measurement circuit includes a first delay circuit, a time-to-digital converter, and a resolution circuit. The first delay circuit is configured to, based on a first clock signal, output a second clock signal. The second clock signal is delayed from the first clock signal. The time-to-digital converter includes a plurality of first delay cells, a plurality of second delay cells, and a plurality of first phase detectors. The plurality of first delay cells are configured to delay the first clock signal, the plurality of second delay cells are configured to delay the second clock signal, and the plurality of first phase detectors are connected between the plurality of first delay cells and the plurality of second delay cells. The time-to-digital converter is configured to output a plurality of first phase detection signals based on the first clock signal, the second clock signal, and a control signal. The resolution circuit is configured to output the control signal to control an amount of delay of the first clock signal, determine, based on the plurality of first phase detection signals, a resolution of the time-to-digital converter as a first resolution, and output a result signal corresponding to a level of a jitter of the first clock signal. The resolution of the time-to-digital converter is configured to change depending on the level of the jitter.

In some implementations, in a method of measuring a jitter, a second clock signal is outputted based on a first clock signal. The second clock signal is delayed from the first clock signal. A plurality of first delay cells delay the first clock signal based on a control signal. A plurality of second delay cells delay the second clock signal. A resolution of a time-to-digital converter is determined as a first resolution based on a phase difference between a plurality of first delay clock signals and a plurality of second delay clock signals. The plurality of first delay clock signals are generated based on passing the first clock signal through the plurality of first delay cells. The plurality of second delay clock signals are generated based on passing the second clock signal through the plurality of second delay cells. The resolution of the time-to-digital converter is configured to adaptively change depending on a level of the jitter of the first clock signal. A result signal corresponding to the level of the jitter based on the first resolution is outputted.

In some implementations, a jitter measurement circuit includes a time-to-digital converter, a first delay circuit, a resolution circuit, a chopper, a signal converter, and a resolution estimation circuit. The time-to-digital converter includes a plurality of first delay cells, a plurality of second delay cells, and a plurality of first phase detectors. The plurality of first delay cells are configured to output a plurality of first delay clock signals by delaying a first clock signal based on a control signal, the plurality of second delay cells configured to output a plurality of second delay clock signals by delaying a second clock signal, the second clock signal is delayed from the first clock signal, the plurality of first phase detectors are connected between the plurality of first delay cells and the plurality of second delay cells. The plurality of first phase detectors are configured to output a plurality of first phase detection signals based on a phase difference between the plurality of first delay clock signals and the plurality of second delay clock signals. The first delay circuit is configured to output the second clock signal based on the first clock signal, and includes a second phase detector configured to output a second phase detection signal based on a phase difference between the first clock signal and the second clock signal. The resolution circuit is configured to output the control signal to control an amount of delay of the first clock signal, determine, based on the plurality of first phase detection signals, a resolution of the time-to-digital converter as a first resolution based on the plurality of first phase detection signals, and output a result signal corresponding to a level of a jitter of the first clock signal. The resolution of the time-to-digital converter is configured to adaptively change depending on the level of the jitter. The chopper is configured to maintain or change a first path of the first clock signal and a second path of the second clock signal based on the first clock signal, the second clock signal, and the second phase detection signal. The signal converter is configured to output a jitter measurement signal based on the result signal and the second phase detection signal. The jitter measurement signal is representing the level of the jitter. The resolution estimation circuit is configured to estimate, based on two first delay clock signals among the plurality of first delay clock signals, a time corresponding to the first resolution based on two first delay clock signals among the plurality of first delay clock signals.

In the jitter measurement circuit and the method of measuring jitter, a resolution for measuring the jitter may be changed depending on a level of the jitter. Thus, the jitter measurement circuit may measure jitter precisely when the jitter is low, and may expand a jitter measurement range when the jitter is high, and thus the jitter measurement circuit may have a flexibility in the jitter measurement. Therefore, an inefficient measurement range occurring in a conventional jitter measurement circuit with fixed resolution may be minimized, and high accuracy and reliability in various frequency environments may be maintained. Additionally, both positive and negative parts of a jitter histogram may be represented using a chopper, and an actual resolution may be estimated using a resolution estimation circuit.

### BRIEF DESCRIPTION OF THE DRAWINGS

Illustrative, non-limiting example implementations will be more clearly understood from the following detailed description taken in conjunction with the accompanying drawings.

FIG. 1 is a block diagram illustrating an example of a jitter measurement circuit.

FIG. 2 is a block diagram illustrating an example of time-to-digital converter and a resolution circuit included in a jitter measurement circuit.

FIG. 3 is a flowchart illustrating an example of a method of measuring a jitter.

FIG. 4 is a flowchart illustrating an example of determining a resolution of a time-to-digital converter as a first resolution in a method of measuring a jitter.

FIG. 5 is a diagram for describing an example of an operation of a resolution circuit in FIG. 2.

FIG. 6 is a block diagram illustrating an example of a first delay circuit included in a jitter measurement circuit.

FIG. 7 is a block diagram illustrating an example of a jitter measurement circuit.

FIGS. 8A and 8B are diagrams illustrating examples of a first delay circuit and a chopper included in a jitter measurement circuit.

FIG. 9 is a block diagram illustrating an example of a jitter measurement circuit.

FIGS. 10A and 10B are diagrams illustrating examples of a chopper and a second delay circuit included in a jitter measurement circuit.

FIG. 11 is a block diagram illustrating an example of a jitter measurement circuit.

FIG. 12 is a block diagram illustrating an example of a jitter measurement circuit.

FIG. 13 is a diagram illustrating an example of resolution estimation circuit included in a jitter measurement circuit.

FIG. 14 is a block diagram illustrating an example of a jitter measurement circuit.

FIG. 15 is a block diagram illustrating an example of a memory system.

### DETAILED DESCRIPTION

Various example implementations will be described more fully with reference to the accompanying drawings, in which implementations are shown. The present disclosure may, however, be implemented in many different forms and should not be construed as limited to the implementations set forth herein. Like reference numerals refer to like elements throughout this application.

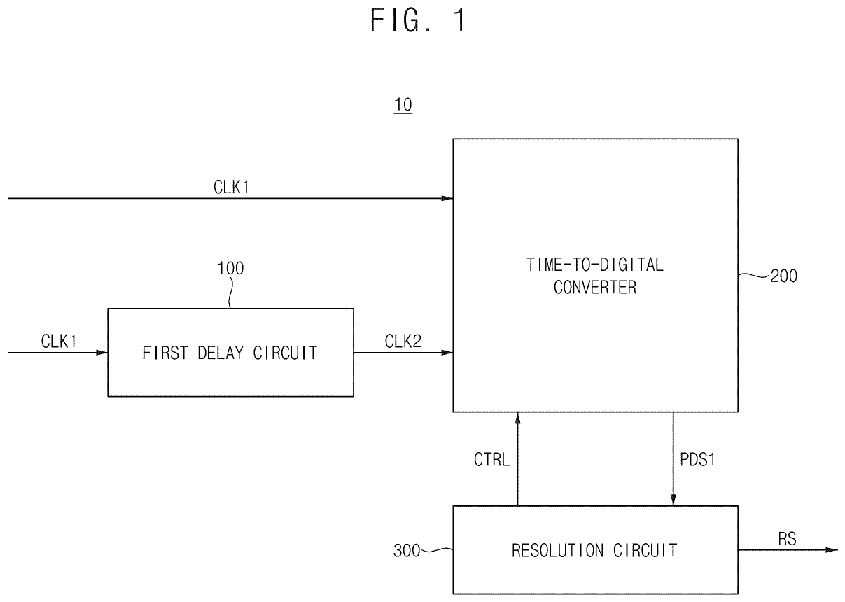

FIG. 1 is a block diagram illustrating an example of a jitter measurement circuit.

Referring to FIG. 1, the jitter measurement circuit 10 includes a first delay circuit 100, a time-to-digital converter 200, and a resolution circuit 300.

The first delay circuit 100 receives a first clock signal CLK1 and outputs a second clock signal CLK2 which is delayed from the first clock signal CLK1 based on the first clock signal CLK1. In other words, the first delay circuit 100 outputs the second clock signal CLK2 by delaying the first clock signal CLK1.

In some implementations, the first delay circuit 100 may output the second clock signal CLK2 by delaying the first clock signal CLK1 by one cycle. However, example implementations are not limited thereto, and the first delay circuit 100 may output the second clock signal CLK2 by delaying the first clock signal CLK1 by two or more cycles.

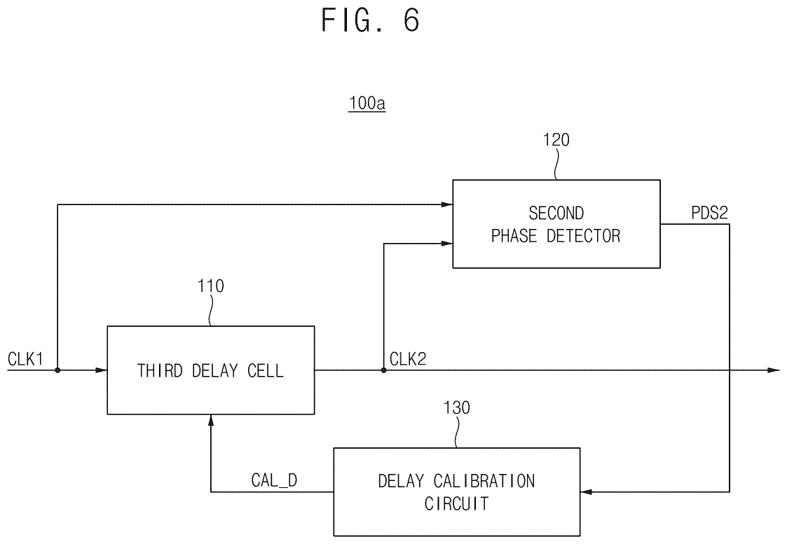

An exemplary configuration of the first delay circuit 100 will be described with reference to FIG. 6.

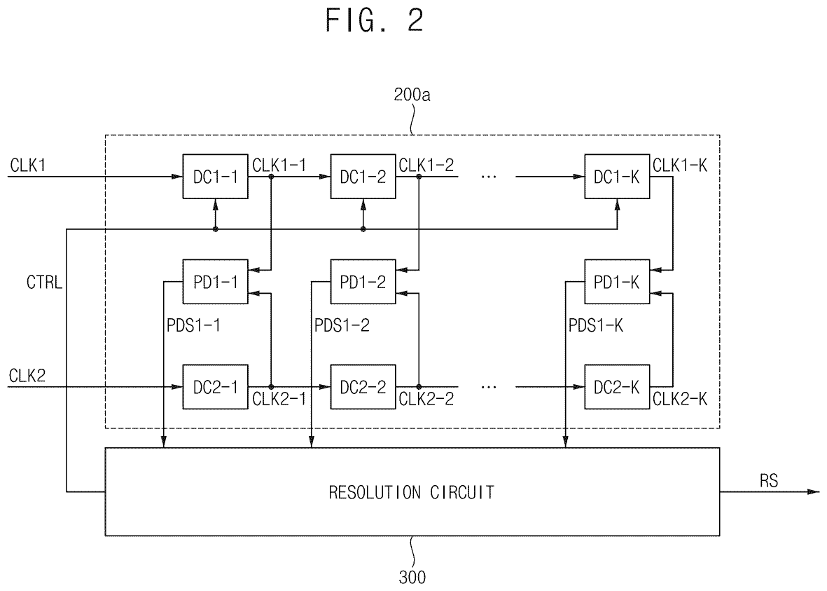

The time-to-digital converter 200 outputs a plurality of first phase detection signals PDS1 based on the first clock signal CLK1, the second clock signal CLK2, and a control signal CTRL. Exemplary configuration and operation of the time-to-digital converter 200 will be described with reference to FIG. 2.

The resolution circuit 300 outputs the control signal CTRL controlling the amount of delay of the first clock signal CLK1 and receives the plurality of first phase detection signals PDS1 from the time-to-digital converter 200. The resolution circuit 300 determines a resolution of the time-to-digital converter 200 as a first resolution based on the plurality of first phase detection signals PDS1. The resolution of the time-to-digital converter 200 adaptively changes depending on a level of a jitter of the first clock signal CLK1. The resolution circuit 300 outputs a result signal RS corresponding to the level of the jitter based on the first resolution. The result signal RS will be described with reference to FIG. 2.

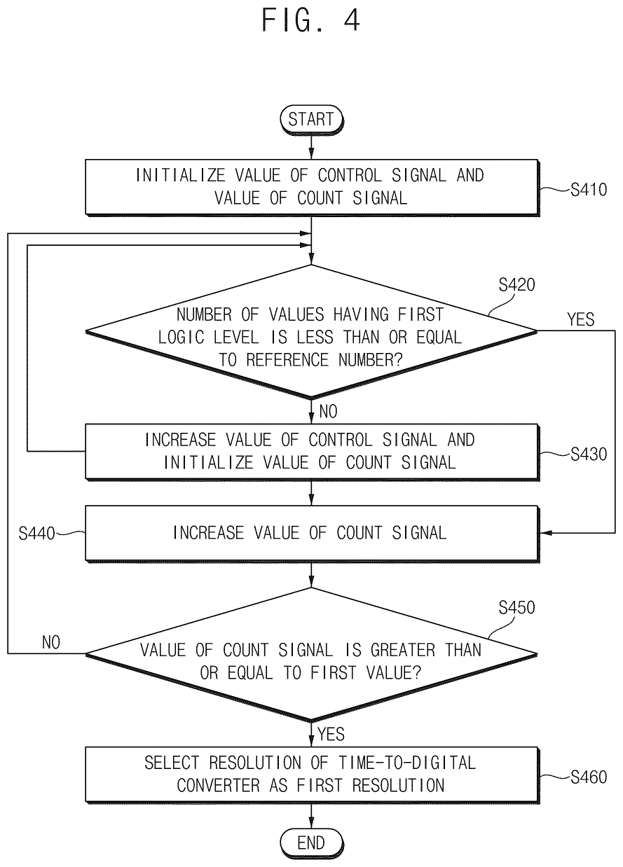

For example, the resolution may represent a minimum time interval which the time-to-digital converter 200 may distinguish. For example, the first resolution may be an optimal resolution determined depending on the level of the jitter of the first clock signal CLK1. An exemplary operation of the resolution circuit 300 will be described with reference to FIG. 4.

Recently, various processing cores and peripheral interfaces are integrated in a system-on-chip (SoC), and thus it is difficult to stably distribute low-jitter clock signals to multiple locations within the chip. For example, as the frequency increases, an allowable jitter tolerance of the clock signal becomes narrower, thereby a need for the jitter measurement circuit capable of providing real-time jitter information is increasing.

A time-to-digital converter (TDC)-based jitter measurement circuit may identify components of the jitter through jitter histograms. Additionally, the TDC-based jitter measurement circuit may measure the full range of instantaneous timing errors at once using a multi-bit quantizer, and thus may accurately measure rapidly changing jitter. For these reasons, the TDC-based jitter measurement circuits may be widely adopted in modern jitter analysis.

However, there was a problem that a conventional TDC-based jitter measurement circuit uses a fixed resolution regardless of a frequency of the clock signal or the level of the jitter. In the TDC-based jitter measurement circuit, it is important to balance between the resolution and the jitter measurement range, but the conventional TDC-based jitter measurement circuit uses the fixed resolution regardless of the frequency of the clock signal or the level of the jitter.

In the jitter measurement circuit 10, the resolution for measuring the jitter may be changed depending on the level of the jitter. Thus, the jitter measurement circuit 10 may measure the jitter precisely when the jitter is low, and may expand the jitter measurement range when the jitter is high, and thus the jitter measurement circuit 10 may have a flexibility in the jitter measurement.

Therefore, an inefficient measurement range occurring in the conventional jitter measurement circuit with fixed resolution may be minimized, and high accuracy and reliability in various frequency environments may be maintained. Additionally, both positive and negative parts of the jitter histogram may be represented using a chopper, and an actual resolution may be estimated using a resolution estimation circuit.

FIG. 2 is a block diagram illustrating an example of time-to-digital converter and a resolution circuit included in a jitter measurement circuit.

Referring to FIG. 2, a time-to-digital converter 200a includes a plurality of first delay cells DC1-1, DC1-2, . . . , DC1-K, a plurality of second delay cells DC2-1, DC2-2, . . . , DC2-K and a plurality of first phase detectors PD1-1, PD1-2, . . . , PD1-K (K is a natural number greater than or equal to three).

The time-to-digital converter 200a and the resolution circuit 300 may be substantially the same as the time-to-digital converter 200 and the resolution circuit 300 in FIG. 1, respectively. Hereinafter, the descriptions repeated with or overlapping with descriptions of FIG. 1 will be omitted in the interest of brevity.

The plurality of first delay cells DC1-1, DC1-2, . . . , DC1-K delay the first clock signal CLK1. A plurality of first delay clock signals CLK1-1, CLK1-2, . . . , CLK1-K may be generated by passing the first clock signal CLK1 through the plurality of first delay cells DC1-1, DC1-2, . . . , DC1-K.

For example, the first delay cell DC1-1 may receive the first clock signal CLK1 and output the first delay clock signal CLK1-1. For example, the first delay cell DC1-2 may receive the first delay clock signal CLK1-1 and output the first delay clock signal CLK1-2. For example, the first delay cell DC1-K may receive a first delay clock signal CLK1-K-1 and output the first delay clock signal CLK1-K.

The plurality of second delay cells DC2-1, DC2-2, . . . , DC2-K delay the second clock signal CLK2. A plurality of second delay clock signals CLK2-1, CLK2-2, . . . , CLK2-K may be generated by passing the second clock signal CLK2 through the plurality of second delay cells DC2-1, DC2-2, . . . , DC2-K.

For example, the second delay cell DC2-1 may receive the second clock signal CLK2 and output the second delay clock signal CLK2-1. For example, the second delay cell DC2-2 may receive the second delay clock signal CLK2-1 and output the second delay clock signal CLK2-2. For example, the second delay cell DC2-K may receive a second delay clock signal CLK2-K-1 and output the second delay clock signal CLK2-K.

The resolution circuit 300 outputs the control signal CTRL, and the plurality of first delay cells DC1-1, DC1-2, . . . , DC1-K receive the control signal CTRL. The amount of delay of the first clock signal CLK1 may be changed by the control signal CTRL.

For example, the control signal CTRL may be generated based on one of the plurality of first phase detection signals (e.g., PDS1 in FIG. 1). The control signal CTRL will be described with reference to FIG. 4.

For example, assuming that the number of bits of the control signal CTRL is six, the control signal CTRL may have a total of sixty-three values from ‘000001’ to ‘111111’ excluding ‘000000’. When the plurality of first delay cells DC1-1, DC1-2, . . . , DC1-K receive the control signal CTRL having a value of ‘000001’, the amount of delay of the first clock signal CLK1 may be minimum, and when the plurality of first delay cells DC1-1, DC1-2, . . . , DC1-K receive the control signal CTRL having a value of ‘111111’, the amount of delay of the first clock signal CLK1 may be maximum.

In other words, the amount of delay of the plurality of first delay cells DC1-1, DC1-2, . . . , DC1-K may vary in proportion to the value of the control signal CTRL.

The amount of delay of the second clock signal CLK2 may be fixed, maintained or unchanged. For example, another control signal having a value of ‘000000’ may be inputted to the plurality of second delay cells DC2-1, DC2-2, . . . , DC2-K in the process of manufacturing. In other words, the plurality of second delay cells DC2-1, DC2-2, . . . , DC2-K may have a smaller amount of delay than the plurality of first delay cells DC1-1, DC1-2, . . . , DC1-K having the minimum amount of delay when the value of the control signal CTRL is ‘000001’.

Although the case where the number of bits of the control signal CTRL is six is exemplified, example implementations are not limited thereto, and the number of bits of the control signal CTRL may be an arbitrary number other than six.

The plurality of first phase detectors PD1-1, PD1-2, . . . , PD1-K are connected between the plurality of first delay cells DC1-1, DC1-2, . . . , DC1-K and the plurality of second delay cells DC2-1, DC2-2, . . . , DC2-K. For example, the first phase detector PD1-1 may be connected between the first delay cell DC1-1 and the second delay cell DC2-1, the first phase detector PD1-2 may be connected between the first delay cell DC1-2 and the second delay cell DC2-2, and the first phase detector PD1-K may be connected between the first delay cell DC1-K and the second delay cell DC2-K.

The plurality of first phase detectors PD1-1, PD1-2, . . . , PD1-K may output a plurality of first phase detector signals PDS1-1, PDS1-2, . . . , PDS1-K based on phase differences between the plurality of first delay clock signals CLK1-1, CLK1-2, . . . , CLK1-K and the plurality of second delay clock signals CLK2-1, CLK2-2, . . . , CLK2-K. The plurality of first delay clock signals CLK1-1, CLK1-2, . . . , CLK1-K are generated by passing the first clock signal CLK1 through the plurality of first delay cells DC1-1, DC1-2, . . . , DC1-K. The plurality of second delay clock signals CLK2-1, CLK2-2, . . . , CLK2-K are generated by passing the second clock signal CLK2 through the plurality of second delay cells DC2-1, DC2-2, . . . , DC2-K.

For example, the first phase detector PD1-1 may receive the first delay clock signal CLK1-1 generated by passing the first clock signal CLK1 through the first delay cell DC1-1 and the second delay clock signal CLK2-1 generated by passing the second clock signal CLK2 through the second delay cell DC2-1. For example, the first phase detector PD1-1 may output the first phase detection signal PDS1-1 based on a phase difference between the first delay clock signal CLK1-1 and the second delay clock signal CLK2-1.

For example, the first phase detector PD1-1 may be a bang-bang phase detector. For example, the first phase detector PD1-1 may output a value of ‘1’ when a phase of the first delay clock signal CLK1-1 leads a phase of the second delay clock signal CLK2-1, and may output a value of ‘0’ when the phase of second delay clock signal CLK2-1 leads the phase of the first delay clock signal CLK1-1.

However, example implementations are not limited thereto, and the first phase detector PD1-1 may output a value of ‘0’ when the phase of the first delay clock signal CLK1-1 leads the phase of the second delay clock signal CLK2-1, and may output a value of ‘1’ when the phase of the second delay clock signal CLK2-1 leads the phase of the first delay clock signal CLK1-1.

For example, the first phase detector PD1-2 may receive the first delay clock signal CLK1-2 generated by passing the first delay clock signal CLK1-1 through the first delay cell DC1-2 and the second delay clock signal CLK2-2 generated by passing the second delay clock signal CLK2-1 through the second delay cell DC2-2. The first phase detector PD1-2 may output the first phase detection signal PDS1-2 based on the first delay clock signal CLK1-2 and the second delay clock signal CLK2-2.

For example, the first phase detector PD1-K may receive the first delay clock signal CLK1-K generated by passing the first delay clock signal CLK1-K-1 through the first delay cell DC1-K and the second delay clock signal CLK2-K generated by passing the second delay clock signal CLK2-K-1 through the second delay cell DC2-K. The first phase detector PD1-K may output the first phase detection signal PDS1-K based on the first delay clock signal CLK1-K and the second delay clock signal CLK2-K.

For example, similar to the first phase detector PD1-1, the first phase detectors PD1-2, . . . , PD1-K may be the bang-bang phase detectors, but example implementations are not limited.

Hereinafter, it is assumed for explanation that the case where each of the plurality of first phase detectors (e.g., PD1-1) outputs a value of ‘0’ when the phase of each of the plurality of first delay clock signals (e.g., CLK1-1) leads the phase of each of the plurality of second delay clock signals (e.g., CLK2-1). Hereinafter, it is assumed for explanation that the case where ‘K=15’, e.g., fifteen first delay cells, fifteen second delay cells and fifteen first phase detectors output fifteen first delay clock signals (e.g., CLK1-1, CLK1-2, CLK1-3, CLK1-4, CLK1-5, CLK1-6, CLK1-7, CLK1-8, CLK1-9, CLK1-10, CLK1-11, CLK1-12, CLK1-13, CLK1-14, CLK1-15), fifteen second delay clock signals (e.g., CLK2-1, CLK2-2, CLK2-3, CLK2-4, CLK2-5, CLK2-6, CLK2-7, CLK2-8, CLK2-9, CLK2-10, CLK2-11, CLK2-12, CLK2-13, CLK2-14, CLK2-15) and fifteen first phase detection signals (e.g., PDS1-1, PDS1-2, PDS1-3, PDS1-4, PDS1-5, PDS1-6, PDS1-7, PDS1-8, PDS1-9, PDS1-10, PDS1-11, PDS1-12, PDS1-13, PDS1-14, PDS1-15), respectively.

In some implementations, assuming that the phase of the first clock signal CLK1 leads the phase of the second clock signal CLK2, and the value of the control signal CTRL is ‘000001’, the plurality of first delay cells DC1-1, DC1-2, . . . , DC1-15 receive the control signal CTRL having the value of ‘000001’, and the amount of delay of the first clock signal CLK1 may be minimal. In contrast, the amount of delay of the second clock signal CLK2 may have the amount of delay corresponding to the control signal having the value of ‘000000’ inputted to the plurality of second delay cells DC2-1, DC2-2, . . . , DC2-15 in the process of manufacturing.

In other words, since the phase of the first clock signal CLK1 leads the phase of the second clock signal CLK2, and the amount of delay of the plurality of first delay cells DC1-1, DC1-2, . . . , DC1-15 is greater than the amount of delay of the plurality of second delay cells DC2-1, DC2-2, . . . , DC2-15, there may exist a moment when the phase of the second clock signal CLK2 leads the phase of the first clock signal CLK1 as the first clock signal CLK1 and the second clock signal CLK2 pass through the plurality of first delay cells DC1-1, DC1-2, . . . , DC1-15 and the plurality of second delay cells DC2-1, DC2-2, . . . , DC2-15, respectively.

For example, when the phase of the first delay clock signal CLK1-1 leads the phase of the second delay clock signal CLK2-1, the first phase detector PD1-1 may output the first phase detection signal PDS1-1 having the value of ‘0’. For example, when the phase of the first delay clock signal CLK1-2 leads the phase of the second delay clock signal CLK2-2, the first phase detector PD1-2 may output the first phase detection signal PDS1-2 having the value of ‘0’. For example, when the phase of the first delay clock signal CLK1-3 leads the phase of the second delay clock signal CLK2-3, the first phase detector PD1-3 may output the first phase detection signal PDS1-3 having the value of ‘0’. For example, when the phase of the second delay clock signal CLK2-4 leads the phase of the first delay clock signal CLK1-4, the first phase detector PD1-4 may output the first phase detection signal PDS1-4 having the value of ‘1’.

In other words, the values of the first phase detection signal PDS1-1, the first phase detection signal PDS1-2, and the first phase detection signal PDS1-3 may be ‘0’, and values of the first phase detection signal PDS1-4 and the plurality of first phase detection signals PDS1-5, PDS1-6, . . . , PDS1-15 may be ‘1’. In this case, the result signal RS may have the value of ‘000111111111111’.

Therefore, assuming that ‘T(000001)’ is defined as the amount of delay of the plurality of first delay cells DC1-1, DC1-2, . . . , DC1-15 when the value of the control signal CTRL is ‘000001’, the resolution of the time-to-digital converter 200a may be ‘T(000001)-T(000000)’. Since the phase of the second clock signal CLK2 leads the phase of the first clock signal CLK1 after the first clock signal CLK1 pass through four first delay cells DC1-1, DC1-2, DC1-3, DC1-4 and the second clock signal CLK2 pass through four second delay cells DC2-1, DC2-2, DC2-3, DC2-4, the amount of the jitter of the first clock signal CLK1 may be ‘4*{T(000001)-T(000000)}’. For example, ‘T(000000)’ may represent the amount of delay of the plurality of second delay cells DC2-1, DC2-2, . . . , DC2-15 corresponding to the control signal having the value of ‘000000’ inputted in the process of manufacturing of the plurality of second delay cells DC2-1, DC2-2, . . . , DC2-15.

Likewise, assuming that the value of the control signal CTRL is ‘110001’, the amount of delay of the plurality of first delay cells DC1-1, DC1-2, . . . , DC1-15 may be ‘T(110001)’. In addition, when the phase of the first clock signal CLK1 leads the phase of the second clock signal CLK2, and the values of the first phase detection signal PDS1-1, the first phase detection signal PDS1-2, the first phase detection signal PDS1-3, the first phase detection signal PDS1-4, and the first phase detection signal PDS1-5 are ‘0’, and the values of the first phase detection signal PDS1-6 and the plurality of first phase detection signals PDS1-7, PDS1-8, . . . , PDS1-K are ‘1’, the result signal RS may have the value of ‘000001111111111’. Therefore, the resolution of the time-to-digital converter 200a may be ‘T(110001)-T(000000)’. Since the phase of the second clock signal CLK2 leads the phase of the first clock signal CLK1 after the first clock signal CLK1 pass through six first delay cells DC1-1, DC1-2, DC1-3, DC1-4, DC1-5, DC1-6 and the second clock signal CLK2 pass through six second delay cells DC2-1, DC2-2, DC2-3, DC2-4, DC2-5, DC2-6, the amount of the jitter of the first clock signal CLK1 may be ‘6*{T(110001)-T(000000)}’.

Likewise, assuming that the value of the control signal CTRL is ‘111111’, the amount of delay of the plurality of first delay cells DC1-1, DC1-2, . . . , DC1-15 may be ‘T(111111)’. In addition, when the phase of the first clock signal CLK1 leads the phase of the second clock signal CLK2, the values of the first phase detection signal PDS1-1 and the first phase detection signal PDS1-2 are ‘0’, and the values of the first phase detection signal PDS1-3 and the plurality of first phase detection signals PDS1-4, PDS1-5, . . . , PDS1-K are ‘1’, the result signal RS may have the value of ‘001111111111111’.

Therefore, the resolution of the time-to-digital converter 200a may be ‘T(111111)-T(000000)’. Since the phase of the second clock signal CLK2 leads the phase of the first clock signal CLK1 after the first clock signal CLK1 pass through three first delay cells DC1-1, DC1-2, DC1-3 and the second clock signal CLK2 pass through three second delay cells DC2-1, DC2-2, DC2-3, and the amount of the jitter of the first clock signal CLK1 may be ‘3*{T(111111)-T(000000)}’.

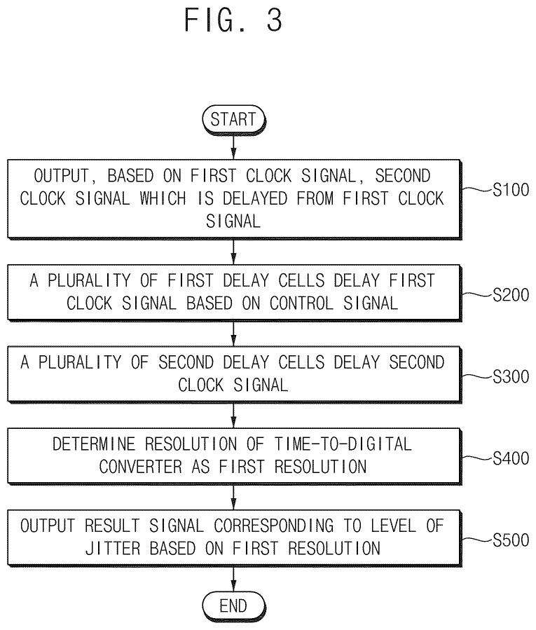

FIG. 3 is a flowchart illustrating an example of a method of measuring a jitter.

Referring to FIG. 3, a method of measuring a jitter may be performed by the jitter measurement circuit (e.g., the jitter measurement circuit 10 of FIG. 1).

As illustrated in FIG. 3, in the method of measuring the jitter, a second clock signal which is delayed from a first clock signal is outputted based on the first clock signal (operation S100).

A plurality of first delay cells delay the first clock signal based on a control signal (operation S200).

A plurality of second delay cells delay the second clock signal (operation S300).

A resolution of a time-to-digital converter is determined as a first resolution based on a phase difference between a plurality of first delay clock signals and a plurality of second delay clock signals (operation S400). The plurality of first delay clock signals are generated by passing the first clock signal through the plurality of first delay cells. The plurality of second delay clock signals are generated by passing the second clock signal through the plurality of second delay cells. The resolution of the time-to-digital converter is adaptively changing depending on a level of the jitter of the first clock signal.

A result signal corresponding to the level of the jitter based on the first resolution is outputted (operation S500).

FIG. 4 is a flowchart illustrating an example of determining a resolution of a time-to-digital converter as a first resolution in a method of measuring a jitter.

Referring to FIGS. 2 and 4, the operation of determining the resolution of the time-to-digital converter as the first resolution may be performed by the resolution circuit 300 in FIG. 2.

When determining the resolution of the time-to-digital converter as the first resolution (operation S400), a value of the control signal and a value of the count counting the number of repetitions of an operation may be initialized (operation S410).

For example, assuming that the number of bits of the control signal CTRL is six, the value of the control signal CTRL may be set to ‘000001’. For example, assuming that the number of bits of the count signal is four, the value of the count signal may be set to ‘0000’.

It may be determined whether the number of values having a first logic level among a plurality of values included in a last first phase detection signal among the plurality of first phase detection signals is less than or equal to a reference number (operation S420).

For example, as illustrated in FIG. 2, the last first phase detection signal among the plurality of first phase detection signals PDS1-1, PDS1-2, . . . , PDS1-K may be the first phase detection signal PDS1-K, and the first logic level may be a logic low level (i.e., ‘0’). In other words, the last first phase detection signal PDS1-K may be generated based on a phase difference between a last first delay clock signal CLK1-K which is generated by passing the first clock signal CLK1 through all the plurality of first delay cells DC1-1, DC1-2, ..., DC1-K and a last second delay clock signal CLK2-K which is generated by passing the second clock signal CLK2 through all the plurality of second delay cells DC2-1, DC2-2, ..., DC2-K.

For example, the resolution circuit 300 may include a 7-bit counter. For example, the 7-bit counter may represent a total of 128 numbers from ‘0000000’ to ‘1111111’, and may increase the number by one from ‘0000000’ to ‘1111111’ whenever the value of the first phase detection signal PDS1-K is received from the first phase detector PD1-K. When the number of the 7-bit counter is ‘1111111’, if the first phase detection signal PDS1-K is received from the first phase detector PD1-K, the number of the 7-bit counter may be reset to ‘0000000’. In other words, the 7-bit counter may be reset whenever the first phase detection signal PDS1-K is received 128 times from the first phase detector PD1-K.

As described with reference to FIG. 2, assuming that ‘T’ is defined as the resolution of the time-to-digital converter 200a, when the amount of the jitter of the first clock signal CLK1 is ‘3*T’, the values of the first phase detection signal PDS1-1 and the first phase detection signal PDS1-2 may be ‘0’, and the values of the first phase detection signal PDS1-3 and the plurality of first phase detection signals PDS1-4, PDS1-5, . . . , PDS1-K may be ‘1’. When the amount of the jitter of the first clock signal CLK1 is ‘6*T’, the values of the first phase detection signal PDS1-1, the first phase detection signal PDS1-2, the first phase detection signal PDS1-3, the first phase detection signal PDS1-4, and the first phase detection signal PDS1-5 may be ‘0’, and the values of the first phase detection signal PDS1-6 and the plurality of first phase detection signals PDS1-7, PDS1-8, . . . , PDS1-K may be ‘1’.

For example, when the amount of the jitter of the first clock signal CLK1 is ‘(K-1)*T’, the values of the plurality of first phase detection signals PDS1-1, PDS1-2, . . . , PDS1-K-1 may be ‘0’, and the values of the first phase detection signal PDS1-K may be ‘1’. For example, when the amount of the jitter of the first clock signal CLK1 is ‘K*T’, the values of all of the plurality of first phase detection signals PDS1-1, PDS1-2, . . . , PDS1-K may be ‘0’.

Therefore, when the value of the first phase detection signal PDS1-K, which is the last first phase detection signal among the plurality of first phase detection signals PDS1-1, PDS1-2, . . . , PDS1-K is ‘0’, the amount of the jitter of the first clock signal CLK1 may be ‘K*T’. In other words, the number of values having the first logic level of ‘0’ among the plurality of values included in the first phase detection signal PDS1-K may be equal to the number of signal having the jitter amount of ‘K*T’, which is the maximum amount of the jitter detectable by the time-to-digital converter 200a.

For example, the number of signal having the jitter amount of ‘K*T’, which is the maximum amount of the jitter detectable by the time-to-digital converter 200a, may be counted by counting the number of values having the first logic level of ‘0’ among the plurality of values included in the first phase detection signal PDS1-K while the 7-bit counter receives the first phase detection signal PDS1-K 128 times from the first phase detector PD1-K.

For example, assuming that the reference number is one, it may be determined whether the number of values having the first logic level of ‘0’ among the plurality of values included in the first phase detection signal PDS1-K while receiving the first phase detection signal PDS1-K 128 times is one or less.

In other words, the resolution circuit 300 may determine whether a probability that the amount of the jitter of the first clock signal CLK1 is ‘K*T’, which is the maximum amount of the jitter detectable by the time-to-digital converter 200a, is equal to or less than 1/128.

When the number of the values having the first logic level is greater than the reference number (operation S420: No), the value of the control signal may be increased and the value of the count signal may be initialized (operation S430).

For example, assuming that the reference number is one, if the probability that the amount of the jitter of the first clock signal CLK1 is ‘K*T’, which is the maximum amount of the jitter detectable by the time-to-digital converter 200a, is more than 1/128, the resolution circuit 300 may increase the value of the control signal CTRL by one, and the value of the count signal may be set to ‘0000’assuming that the number of bits of the count signal is four.

For example, the control signal CTRL may be changed based on the number of values having the first logic level of ‘0’ among the plurality of values included in the first phase detection signal PDS1-K, and the amount of delay of the plurality of first delay cells DC1-1, DC1-2, . . . , DC1-K may be changed based on the control signal CTRL, and the resolution of the time-to-digital converter 200a may be changed based on the amount of delay of the plurality of first delay cells DC1-1, DC1-2, . . . , DC1-K.

When the number of the values having the first logic level is less than or equal to the reference number (operation S420: Yes), the value of the count signal may be increased (operation S440).

For example, assuming that the reference number is one, if the probability that the amount of the jitter of the first clock signal CLK1 is ‘K*T’, which is the maximum amount of the jitter detectable by the time-to-digital converter 200a, is equal to or less than 1/128, the resolution circuit 300 may increase the value of the count signal by one.

It may be determined whether the value of the count signal is greater than or equal to the first value (operation S450).

For example, assuming that the number of bits of the count signal is four, the first value may be ‘1000’. For example, it may be determined whether the value of the count signal is greater than or equal to ‘1000’.

When the value of the count signal is less than the first value (operation S450: No), it may be determined whether the number of values having the first logic level among the plurality of values included in the last first phase detection signal among the plurality of first phase detection signals is less than or equal to the reference number (operation S420).

When the value of the count signal is greater than or equal to the first value (operation S450: yes), the resolution of the time-to-digital converter may be selected as the first resolution (operation S460).

For example, assuming that the number of bits of the count signal is four and the first value is ‘1000’, if the value of the count signal is greater than or equal to ‘1000’, the resolution of the time-to-digital converter 200a in this case may be selected as the first resolution, which is the optimal resolution.

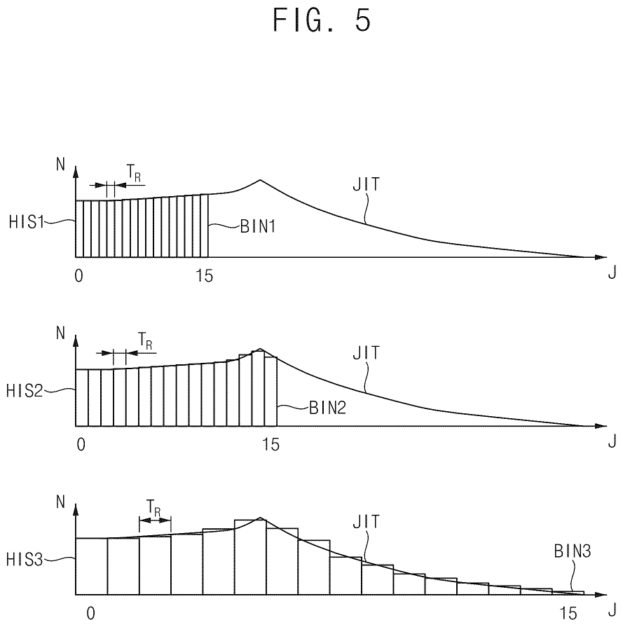

FIG. 5 is a diagram for describing an example of an operation of a resolution circuit in FIG. 2.

Referring to FIGS. 2, 4, and 5, FIG. 5 illustrates a plurality of jitter histograms HIS1, HIS2, HIS3. In the plurality of jitter histograms HIS1, HIS2, HIS3, a horizontal axis J represents the amount of the jitter, and a vertical axis N represents the number of values of the clock signal having the amount of the jitter. A unit of the horizontal axis J is a resolution T_{R}, and a unit of the vertical axis N is the number. In other words, one square of the horizontal axis J may represent the resolution T_{R} of the time-to-digital converter 200a.

In the plurality of jitter histograms HIS1, HIS2, HIS3, a curve graph JIT represents a real jitter profile of the clock signal. In the plurality of jitter histograms HIS1, HIS2, HIS3, the number of the plurality of first delay cells DC1-1, DC1-2, . . . , DC1-K, the number of the plurality of second delay cells DC2-1, DC2-2, . . . , DC2-K, the number of the plurality of first phase detectors PD1-1, PD1-2, . . . , PD1-K, and the number of the plurality of first phase detection signals PDS1-1, PDS1-2, . . . , PDS1-K may be fifteen. In other words, K may be fifteen.

For example, the jitter histogram HIS1 may represent a jitter distribution when the value of the control signal CTRL is ‘000001’. A first bar BIN1, which is a bar located at the rightmost end in the jitter histogram HIS1, may represent the number of signal having the jitter amount of ‘15*T_{R}’, which is the maximum amount of the jitter detectable by the time-to-digital converter 200a.

For example, it may be determined whether the number of values having the first logic level among the plurality of values included in the last first phase detection signal among the plurality of first phase detection signals is less than or equal to the reference number (operation S420 in FIG. 4). For example, the last first phase detection signal among the plurality of first phase detection signals PDS1-1, PDS1-2, . . . , PDS1-15 may be the first phase detection signal PDS1-15, and the first logic level may be a logic low level (i.e., ‘0’).

For example, as described with reference to FIG. 4, in the jitter histogram HIS1, if the probability that the amount of the jitter of the first clock signal CLK1 is ‘15*T_{R}’, which is the maximum amount of the jitter detectable by the time-to-digital converter 200a, is greater than 1/128, it may be determined that the resolution T_{R} is too small relative to the amount of the jitter of the first clock signal CLK1. In this case, a significant portion of the jitter measurement range may be unused and thus wasted, resulting in inefficiency. Therefore, the resolution circuit 300 may increase the resolution T_{R} by increasing the control signal CTRL.

For example, the jitter histogram HIS2 may represent the jitter distribution when the value of the control signal CTRL is ‘000011’. A second bar BIN2, which is a bar located at the rightmost end in the jitter histogram HIS2, may represent the number of signal having the jitter amount of ‘15*T_{R}’, which is the maximum amount of the jitter detectable by the time-to-digital converter 200a.

For example, in the jitter histogram HIS2, if the probability that the amount of the jitter of the first clock signal CLK1 is ‘15*T_{R}’, which is the maximum amount of the jitter detectable by the time-to-digital converter 200a, is greater than 1/128, it may be determined that the resolution T_{R} is still too small relative to the amount of the jitter of the first clock signal CLK1. Therefore, the resolution circuit 300 may increase the resolution T_{R} by increasing the control signal CTRL.

For example, the jitter histogram HIS3 may represent the jitter distribution when the value of the control signal CTRL is ‘001111’. A third bar BIN3, which is a bar located at the rightmost end in the jitter histogram HIS3, may represent the number of signal having the jitter amount of ‘15*T_{R}’, which is the maximum amount of the jitter detectable by the time-to-digital converter 200a.

For example, in the jitter histogram HIS3, if the probability that the amount of the jitter of the first clock signal CLK1 is ‘15*T_{R}’, which is the maximum amount of the jitter detectable by the time-to-digital converter 200a, is equal to or less than 1/128, it may be determined that the resolution T_{R} is appropriately selected relative to the amount of the jitter of the first clock signal CLK1. In this case, there is no unused or wasted jitter measurement range, and the jitter of the first clock signal CLK1 may be measured precisely. Therefore, the resolution circuit 300 may determine the resolution of the time-to-digital converter 200a in this case as the first resolution, which is the optimal resolution.

Although FIG. 5 illustrates the number of the plurality of first delay cells DC1-1, DC1-2, . . . , DC1-K, the number of the plurality of second delay cells DC2-1, DC2-2, . . . , DC2-K, the number of the plurality of first phase detectors PD1-1, PD1-2, . . . , PD1-K, and the number of the plurality of first phase detection signals PDS1-1, PDS1-2, . . . , PDS1-K are fifteen (i.e., K is fifteen), example implementations are not limited thereto, and K may be an arbitrary number other than fifteen.

FIG. 6 is a block diagram illustrating an example of a first delay circuit included in a jitter measurement circuit.

Referring to FIG. 6, a first delay circuit 100a may include a third delay cell 110, a second phase detector 120, and a delay calibration circuit 130. The first delay circuit 100a may be substantially the same as the first delay circuit 100 in FIG. 1. Hereinafter, the descriptions repeated with or overlapping with descriptions of FIG. 1 will be omitted in the interest of brevity.

For example, the first delay circuit 100a may output the second clock signal CLK2 by delaying the first clock signal CLK1 by one cycle. In this case, an error may occur in the process of delaying the first clock signal CLK1 by exactly one cycle.

The third delay cell 110 may output the second clock signal CLK2 based on the first clock signal CLK1 and a delay calibration signal CLK_D for calibrating the error.

The second phase detector 120 may output the second phase detection signal PDS2 based on the phase difference between the first clock signal CLK1 and the second clock signal CLK2.

For example, the second phase detector 120 may be the bang-bang phase detector. For example, the second phase detector 120 may output ‘1’ when the phase of the first clock signal CLK1 leads the phase of the second clock signal CLK2, and may output ‘0’ when the phase of the second clock signal CLK2 leads the phase of the first clock signal CLK1.

However, example implementations are not limited thereto, and the second phase detector 120 may output ‘0’ when the phase of the first clock signal CLK1 leads the phase of the second clock signal CLK2, and may output ‘1’ when the phase of the second clock signal CLK2 leads the phase of the first clock signal CLK1.

The delay calibration circuit 130 may output the delay calibration signal CAL_D for calibrating the amount of delay of the first clock signal CLK1 based on the second phase detection signal PDS2.

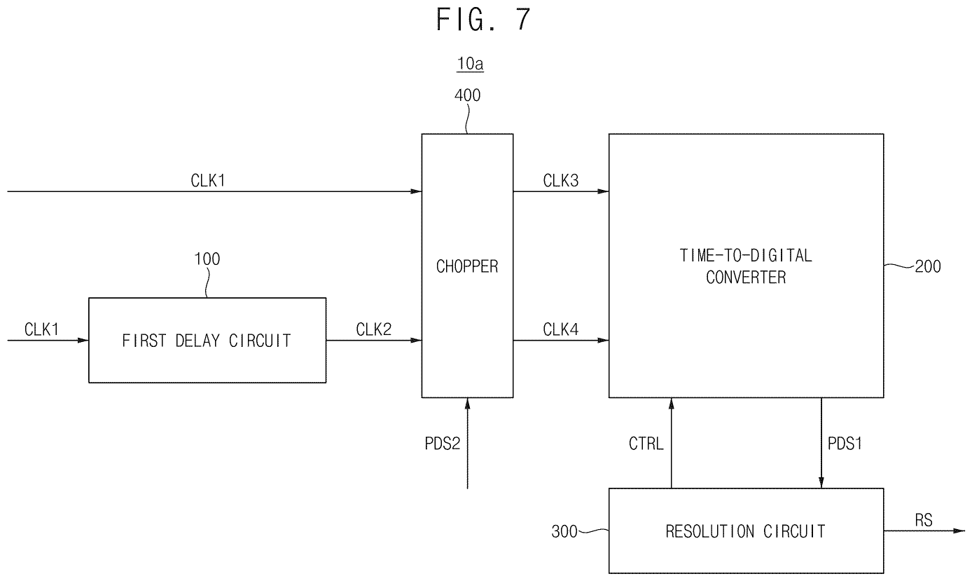

FIG. 7 is a block diagram illustrating an example of a jitter measurement circuit.

Referring to FIG. 7, a jitter measurement circuit 10a may further include a chopper 400 compared to the jitter measurement circuit 10 of FIG. 1. Hereinafter, the descriptions repeated with or overlapping with descriptions of FIG. 1 will be omitted in the interest of brevity.

In some implementations, the chopper 400 may output a third clock signal CLK3 and a fourth clock signal CLK4 based on the first clock signal CLK1, the second clock signal CLK2, and the second phase detection signal PDS2. For example, the chopper 400 may receive the second phase detection signal PDS2 from the second phase detector (e.g., 120 in FIG. 6).

For example, the chopper 400 may maintain or change a first path of the first clock signal CLK1 and a second path of the second clock signal CLK2. For example, due to the characteristics of the time-to-digital converter (e.g., 200a in FIG. 2), the phase of the clock signal received by the plurality of first delay cells (e.g., DC1-1, DC1-2, . . . , DC1-K in FIG. 2) is required to lead the phase of the clock signal received by the plurality of second delay cells (e.g., DC2-1, DC2-2, . . . , DC2-K in FIG. 2). Accordingly, the chopper 400 may perform a function of changing the first path of the first clock signal CLK1 and the second path of the second clock signal CLK2 when the phase of the second clock signal CLK2 leads the first clock signal CLK1, such that the phase of the clock signal received by the plurality of first delay cells DC1-1, DC1-2, . . . , DC1-K leads the phase of the clock signal received by the plurality of second delay cells DC2-1, DC2-2, . . . , DC2-K.

For example, if the phase of the first clock signal CLK1 leads the phase of the second clock signal CLK2, the value of the second phase detection signal PDS2 may be ‘0’. In this case, the chopper 400 may maintain the first path of the first clock signal CLK1 and the second path of the second clock signal CLK2. In other words, the chopper 400 may output the first clock signal CLK1 as the third clock signal CLK3 and output the second clock signal CLK2 as the fourth clock signal CLK4.

For example, if the phase of the second clock signal CLK2 leads the phase of the first clock signal CLK1, the value of the second phase detection signal PDS2 may be ‘1’. In this case, the chopper 400 may change the first path of the first clock signal CLK1 and the second path of the second clock signal CLK2. In other words, the chopper 400 may output the second clock signal CLK2 as the third clock signal CLK3 and the first clock signal CLK1 as the fourth clock signal CLK4.

For example, the time-to-digital converter 200 may output the plurality of first phase detection signals PDS1 based on the third clock signal CLK3, the fourth clock signal CLK4, and the control signal CTRL.

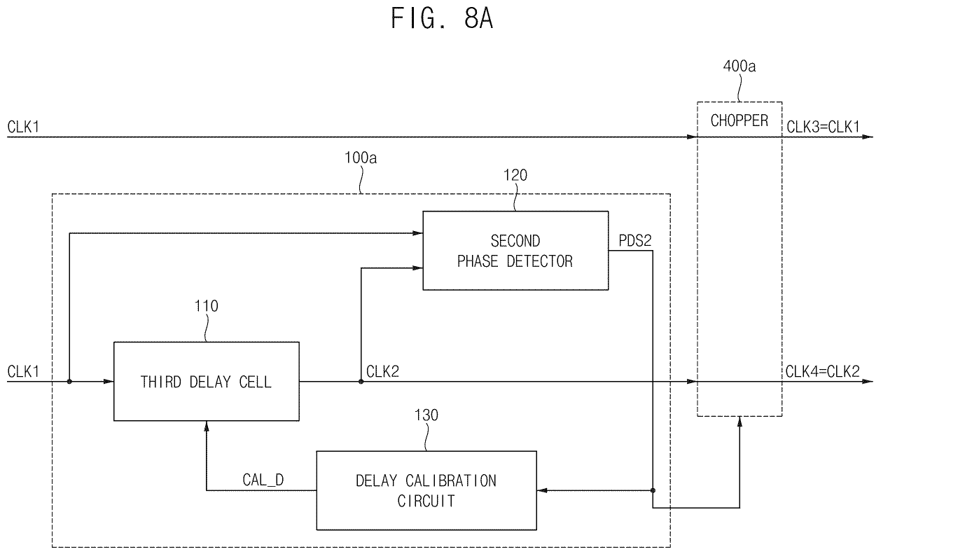

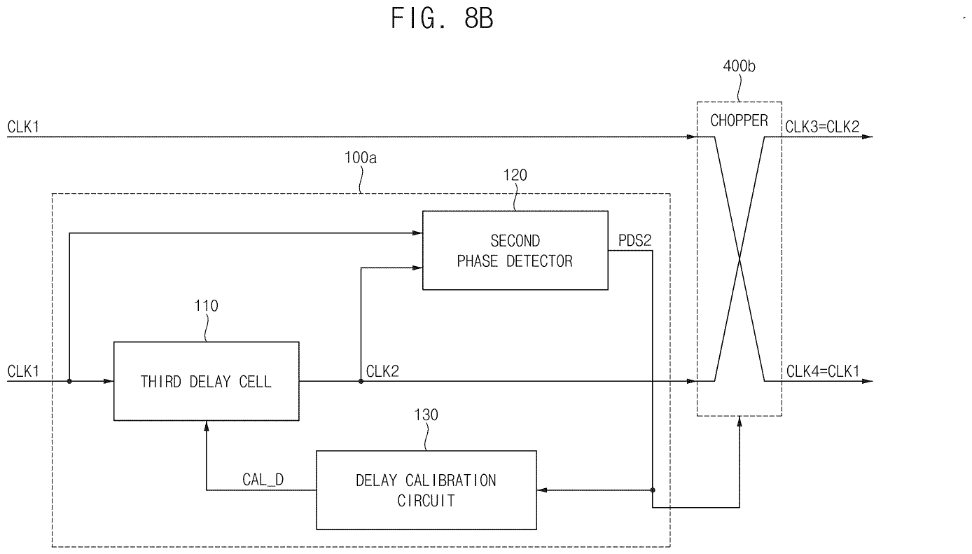

FIGS. 8A and 8B are diagrams illustrating examples of a first delay circuit and a chopper included in a jitter measurement circuit.

Referring to FIG. 8A, the first delay circuit 100a and a chopper 400a may be substantially the same as the first delay circuit 100a in FIG. 6 and the chopper 400 in FIG. 7, respectively. Hereinafter, the descriptions repeated with or overlapping with descriptions of FIGS. 6 and 7 will be omitted in the interest of brevity.

For example, when the phase of the first clock signal CLK1 leads the phase of the second clock signal CLK2, the value of the second phase detection signal PDS2 may be ‘0’. In this case, the chopper 400 may not need to change the first path of the first clock signal CLK1 and the second path of the second clock signal CLK2.

Accordingly, the chopper 400a may maintain the first path of the first clock signal CLK1 and the second path of the second clock signal CLK2, output the second clock signal CLK2 as the third clock signal CLK3, and output the first clock signal CLK1 as the fourth clock signal CLK4.

Referring to FIG. 8B, the first delay circuit 100a and a chopper 400b may be substantially the same as the first delay circuit 100a in FIG. 6 and the chopper 400 in FIG. 7, respectively. Hereinafter, the descriptions repeated with or overlapping with descriptions of FIGS. 6 and 7 will be omitted in the interest of brevity.

For example, when the phase of the second clock signal CLK2 leads the phase of the first clock signal CLK1, the second phase detection signal PDS2 may be ‘1’. In this case, the chopper 400b may need to change the first path of the first clock signal CLK1 and the second path of the second clock signal CLK2.

Accordingly, the chopper 400b may change the first path of the first clock signal CLK1 and the second path of the second clock signal CLK2, output the second clock signal CLK2 as the third clock signal CLK3, and output the first clock signal CLK1 as the fourth clock signal CLK4.

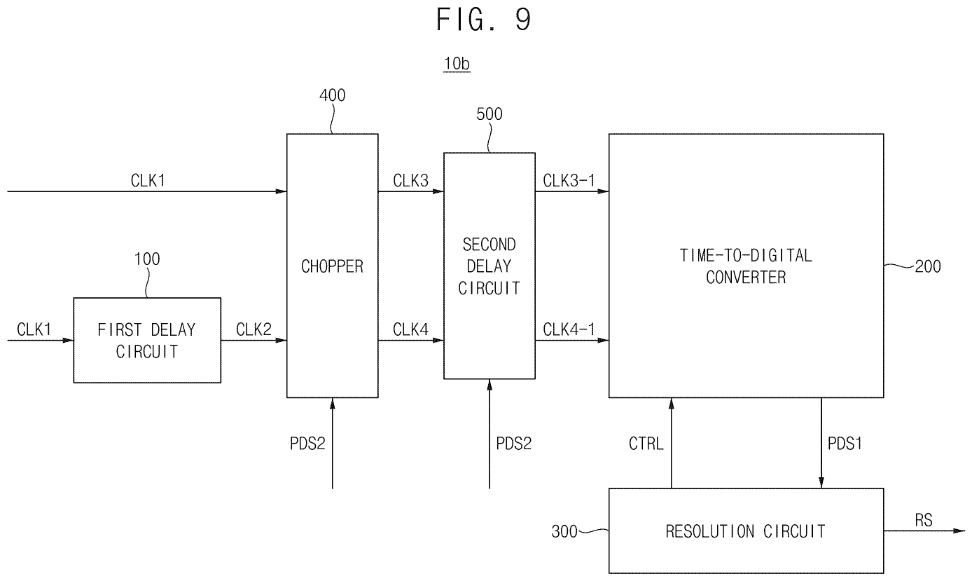

FIG. 9 is a block diagram illustrating an example of a jitter measurement circuit.

Referring to FIG. 9, a jitter measurement circuit 10b may further include a second delay circuit 500 compared to the jitter measurement circuit 10a of FIG. 7. Hereinafter, the descriptions repeated with or overlapping with descriptions of FIGS. 1 and 7 will be omitted in the interest of brevity.

For example, an error may occur in the process of passing the first clock signal CLK1 and the second clock signal CLK2 through the chopper 400. The error may be referred to as a chopper offset. The chopper offset may occur in one of the third clock signal CLK3 and the fourth clock signal CLK4 by the chopper 400.

For example, the second delay circuit 500 may perform a function of calibrate the chopper offset based on the third clock signal CLK3 and the fourth clock signal CLK4 received from the chopper 400 and the second phase detection signal PDS2. For example, the second delay circuit 500 may receive the second phase detection signal PDS2 from the second phase detector (e.g., 120 in FIG. 6). For example, the second delay circuit 500 may output a third-first clock signal CLK3-1 and a fourth-first clock signal CLK4-1 by calibrating the chopper offset.

For example, the time-to-digital converter 200 may output the plurality of first phase detection signals PDS1 based on the third-first clock signal CLK3-1, the fourth-first clock signal CLK4-1, and the control signal CTRL.

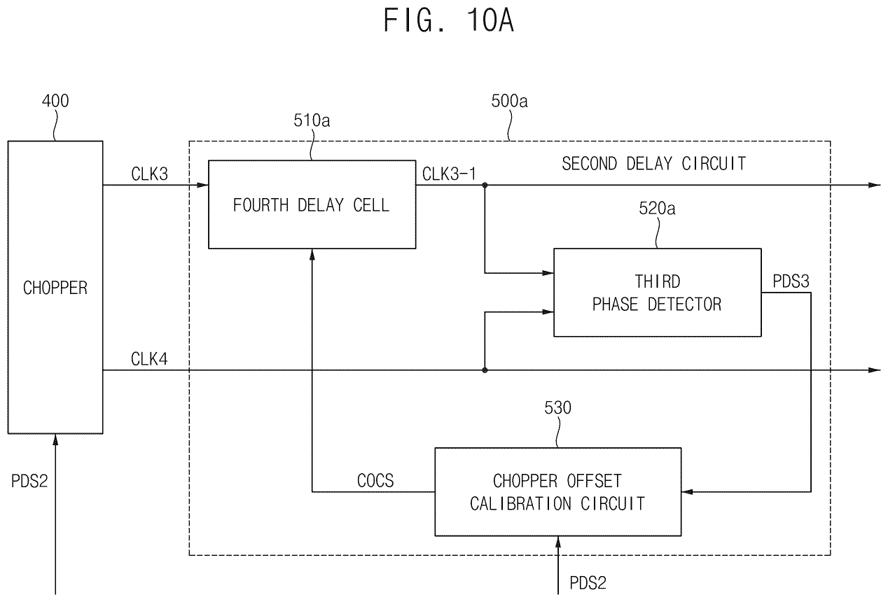

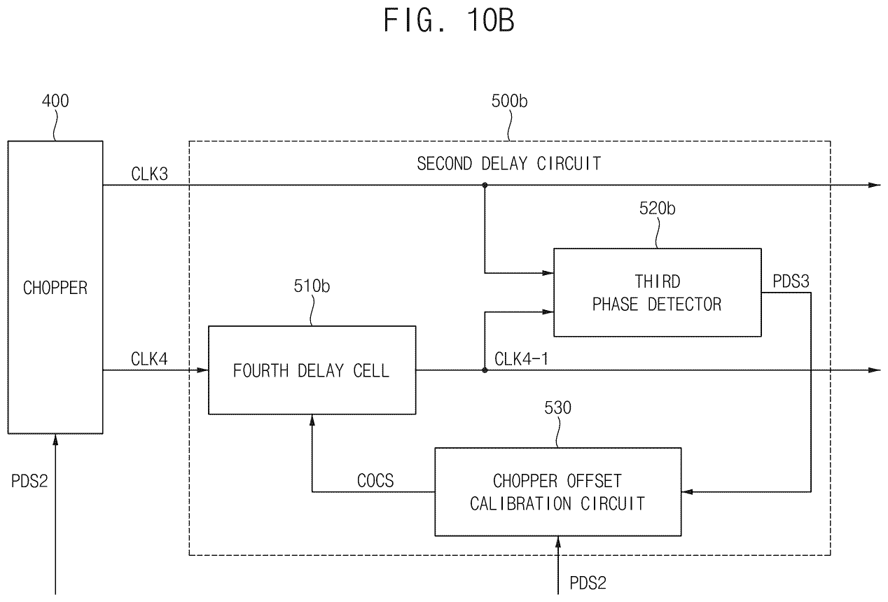

FIGS. 10A and 10B are diagrams illustrating examples of a chopper and a second delay circuit included in a jitter measurement circuit.

Referring to FIG. 10A, the chopper 400 and a second delay circuit 500a may be substantially the same as the chopper 400 and the second delay circuit 500 in FIG. 9, respectively. Hereinafter, the descriptions repeated with or overlapping with descriptions of FIG. 9 will be omitted in the interest of brevity.

In some implementations, the second delay circuit 500a may include a fourth delay cell 510a, a third phase detector 520a, and a chopper offset calibration circuit 530.

For example, the fourth delay cell 510a may receive a chopper offset calibration signal COCS for calibrating the chopper offset from the chopper offset calibration circuit 530, and may receive the third clock signal CLK3 from the chopper 400. For example, the fourth delay cell 510a may output the third-first clock signal CLK3-1 by calibrating the chopper offset.

For example, the third phase detector 520a may output a third phase detection signal PDS3 based on a phase difference between the third-first clock signal CLK3-1 received from the fourth delay cell 510a and the fourth clock signal CLK4 received from the chopper 400.

For example, the third phase detector 520a may be the bang-bang phase detector. For example, the third phase detector 520a may output ‘1’ when the phase of the third-first clock signal CLK3-1 leads the phase of the fourth clock signal CLK4, and may output ‘0’ when the phase of the fourth clock signal CLK4 leads the phase of the third-first clock signal CLK3-1.

However, example implementations are not limited thereto, and the third phase detector 520a may output ‘0’ when the phase of the third-first clock signal CLK3-1 leads the phase of the fourth clock signal CLK4, and may output ‘1’ when the phase of the fourth clock signal CLK4 leads the phase of the third-first clock signal CLK3-1.

For example, the chopper offset calibration circuit 530 may output the chopper offset calibration signal COCS for calibrating the chopper offset based on the second phase detection signal PDS2 and the third phase detection signal PDS3. For example, the chopper offset calibration circuit 530 may receive the second phase detection signal PDS2 from the second phase detector (e.g., 120 in FIG. 6).

For example, the time-to-digital converter 200 may output the plurality of first phase detection signals PDS1 based on the third-first clock signal CLK3-1, the fourth clock signal CLK4, and the control signal CTRL.

Referring to FIG. 10B, the chopper 400 and a second delay circuit 500b may be substantially the same as the chopper 400 and the second delay circuit 500 in FIG. 9, respectively. Hereinafter, the descriptions repeated with or overlapping with descriptions of FIG. 9 will be omitted in the interest of brevity.

In some implementations, the second delay circuit 500b may include a fourth delay cell 510b, a third phase detector 520b, and the chopper offset calibration circuit 530. For example, the fourth delay cell 510b may receive the chopper offset calibration signal COCS for calibrating the chopper offset from the chopper offset calibration circuit 530 and may receive the fourth clock signal CLK4 from the chopper 400. For example, the fourth delay cell 510b may output the fourth-first clock signal CLK4-1 by calibrating the chopper offset.

For example, the third phase detector 520b may output the third phase detection signal PDS3 based on a phase difference between the fourth-first clock signal CLK4-1 received from the fourth delay cell 510b and the third clock signal CLK3 received from the chopper 400.

For example, the third phase detector 520b may be the bang-bang phase detector. For example, the third phase detector 520b may output ‘1’ when the phase of the third clock signal CLK3 leads the phase of the fourth-first clock signal CLK4-1, and may output ‘0’ when the phase of the fourth-first clock signal CLK4-1 leads the phase of the third clock signal CLK3.

However, example implementations are not limited thereto, and the third phase detector 520b may output ‘0’ when the phase of the third clock signal CLK3 leads the phase of the fourth-first clock signal CLK4-1, and may output ‘1’ when the phase of the fourth-first clock signal CLK4-1 leads the phase of the third clock signal CLK3.

For example, the chopper offset calibration circuit 530 may output the chopper offset calibration signal COCS for calibrating the chopper offset based on the second phase detection signal PDS2 and the third phase detection signal PDS3. For example, the chopper offset calibration circuit 530 may receive the second phase detection signal PDS2 from the second phase detector (e.g., 120 in FIG. 6).

For example, the time-to-digital converter 200 may output the plurality of first phase detection signals PDS1 based on the third clock signal CLK3, the fourth-first clock signal CLK4-1, and the control signal CTRL.

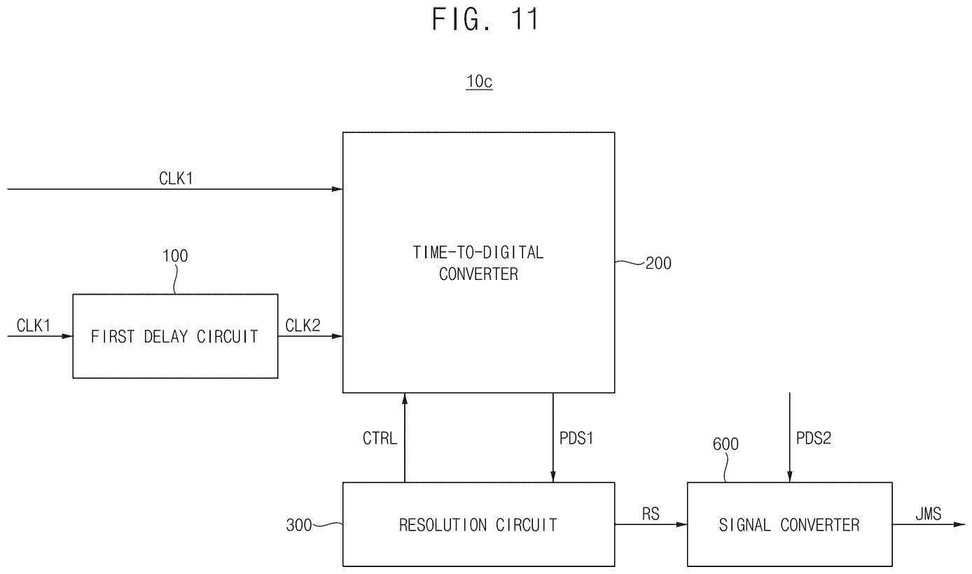

FIG. 11 is a block diagram illustrating an example of a jitter measurement circuit.

Referring to FIG. 11, a jitter measurement circuit 10c may further include a signal converter 600 compared to the jitter measurement circuit 10 of FIG. 1. Hereinafter, the descriptions repeated with or overlapping with descriptions of FIG. 1 will be omitted in the interest of brevity.

The signal converter 600 may receive the result signal RS from the resolution circuit 300 and output a jitter measurement signal JMS representing the level of the jitter based on the result signal RS and the second phase detection signal PDS2.

Referring to FIGS. 2 and 11, the result signal RS may represent a signal in which the plurality of first phase detection signals PDS1-1, PDS1-2, . . . , PDS1-K are sequentially arranged. For example, the values of the plurality of first phase detection signals PDS1-1, PDS1-2, PDS1-3 may be ‘0’, and the values of the first phase detection signals PDS1-4, PDS1-5, . . . , PDS1-K may be ‘1’. For example, assuming that K is fifteen, the value of the result signal RS may be ‘000111111111111’.

For example, the signal converter 600 may convert the result signal RS into a thermometer code format. The thermometer code format refers to a scheme in which signals are arranged in an order where the number of ‘1’ bits increases sequentially, starting from the signal with the fewest number of ‘1’bits.

As described with reference to FIGS. 2, 4, and 5, if the first phase detection signal among the plurality of first phase detection signals PDS1-1, PDS1-2, . . . , PDS1-K in which the signal transitions from ‘0’ to '1′ is the first phase detection signal PDS1-a (a is a natural number greater than or equal to 1 and less than or equal to K), the amount of the jitter of the first clock signal CLK1 may be ‘a*T_{R}’(T_{R} is the resolution of the time-to-digital converter).

For example, the signal converter 600 may output only the ‘a’, excluding ‘T_{R}’ among ‘a*TR’, which represents the amount of the jitter of the first clock signal CLK1, as the jitter measurement signal JMS.

In other words, the signal converter 600 may convert the result signal RS into the thermometer code format, and if the first occurrence of a ‘1’ bit in the converted signal appears at the b-th position from the left (where ‘b’ is a natural number), the signal converter 600 may output ‘b’as the jitter measurement signal JMS.

For example, if the value of the converted signal is ‘000111’, the first ‘1’ bit appears at the fourth position from the left, and thus, the signal converter 600 may output ‘4’ as the jitter measurement signal JMS. In this case, the amount of the jitter of the first clock signal CLK1 may be ‘4×T_{R}’.

For example, the signal converter 600 may receive the second phase detection signal PDS2 from the second phase detector (e.g., 120 in FIG. 6). For example, if the phase of the second clock signal CLK2 leads the phase of the first clock signal CLK1, the value of the second phase detection signal PDS2 may be ‘1’. In this case, the chopper (e.g., 400 in FIG. 7) may change the first path of the first clock signal CLK1 and the second path of the second clock signal CLK2.

For example, assuming that the jitter is positive when the phase of the first clock signal CLK1 leads the phase of the second clock signal CLK2, the jitter may be negative when the phase of the second clock signal CLK2 leads the phase of the first clock signal CLK2.

For example, when the phase of the second clock signal CLK2 leads the phase of the first clock signal CLK1, the value of the second phase detection signal PDS2 may be ‘1’, and the signal converter 600 may output a negative number as the jitter measurement signal JMS based on the second phase detection signal PDS2 received from the second phase detector 120.

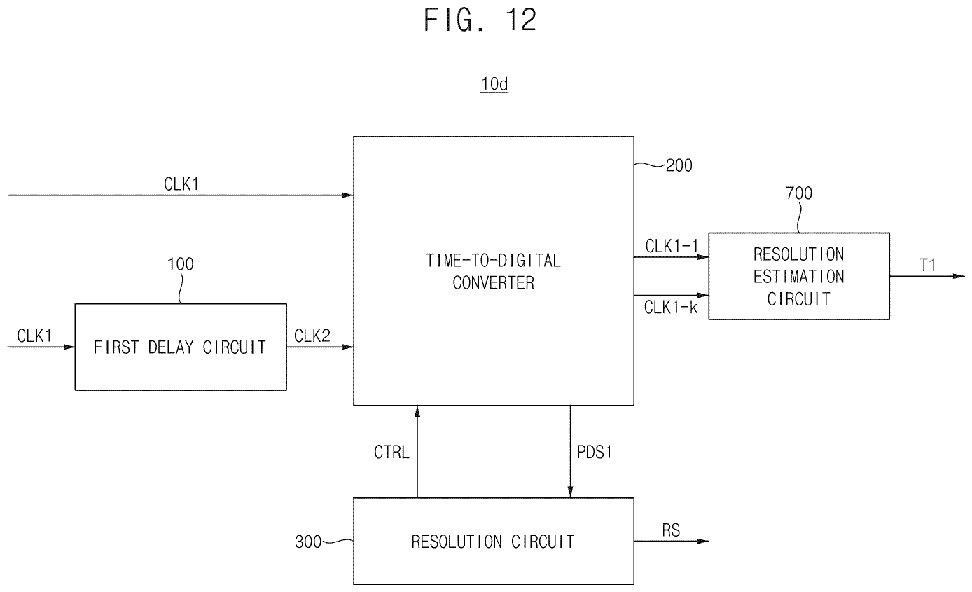

FIG. 12 is a block diagram illustrating an example of a jitter measurement circuit.

Referring to FIG. 12, a jitter measurement circuit 10d may further include a resolution estimation circuit 700 compared to the jitter measurement circuit 10 of FIG. 1. Hereinafter, the descriptions repeated with or overlapping with descriptions of FIG. 1 will be omitted in the interest of brevity.

In some implementations, when the first resolution, which is the optimal resolution determined depending on the level of the jitter of the first clock signal CLK1, is determined, the resolution estimation circuit 700 may estimate a time corresponding to the first resolution.

Referring to FIGS. 2 and 12, the resolution estimation circuit 700 may receive the first delay clock signal CLK1-1 and the first delay clock signal CLK1-K among the plurality of first delay clock signals CLK1-1, CLK1-2, . . . , CLK1-K.

For example, the resolution estimation circuit 700 may estimate a resolution time T1, which is a time corresponding to the first resolution, based on the first delay clock signal CLK1-1 and the first delay clock signal CLK1-K, and may output the resolution time T1.

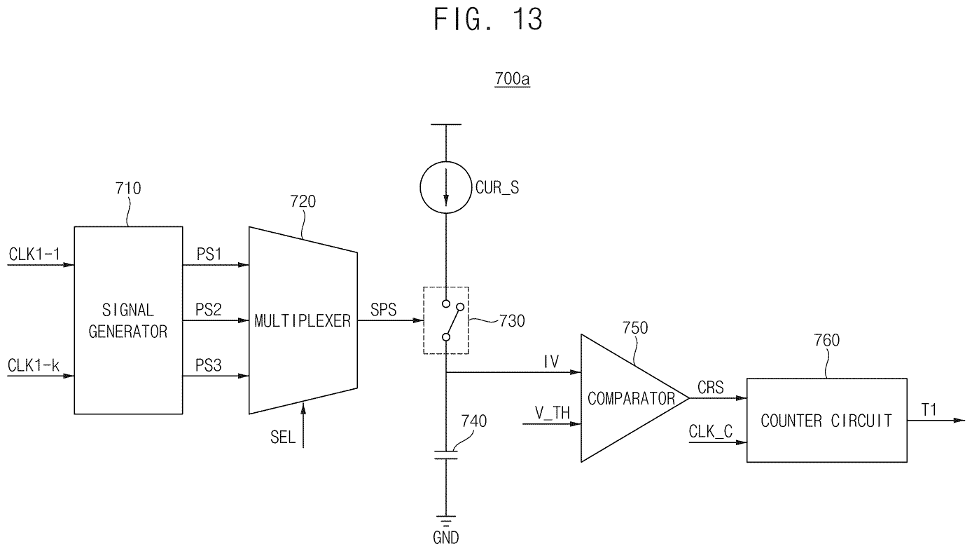

FIG. 13 is a diagram illustrating an example of resolution estimation circuit included in a jitter measurement circuit.

Referring to FIG. 13, a resolution estimation circuit 700a may include a signal generator 710, a multiplexer 720, a switch 730, a capacitor 740, a comparator 750, a counter circuit 760, and a current source CUR_S. The resolution estimation circuit 700a may be substantially the same as the resolution estimation circuit 700 in FIG. 12. Hereinafter, the descriptions repeated with or overlapping with descriptions of FIG. 12 will be omitted in the interest of brevity.

The signal generator 710 may receive the first delay clock signal CLK1-1 and the first delay clock signal CLK1-K among the plurality of first delay clock signals (e.g., CLK1-1, CLK1-2, . . . , CLK1-K in FIG. 2), and may output a first pulse signal PS1, a second pulse signal PS2, and a third pulse signal PS3 based on the first delay clock signal CLK1-1 and the first delay clock signal CLK1-K.

For example, the first pulse signal PS1 may be a pulse signal having a pulse width of one cycle of the first delay clock signal CLK1-1.

For example, the second pulse signal PS2) may be a pulse signal having a pulse width equal to an interval between a rising edge of the first delay clock signal CLK1-1 and a rising edge of the first delay clock signal CLK1-K when the value of the control signal (e.g., CTRL in FIG. 2) is ‘000000’.

For example, the third pulse signal PS3 may be a pulse signal having a pulse width equal to an interval between the rising edge of the first delay clock signal CLK1-1 and the rising edge of the first delay clock signal CLK1-K when the resolution of the time-to-digital converter (e.g., 200a in FIG. 2) is the first resolution, which is the optimal resolution determined depending on the level of the jitter of the first clock signal CLK1.

The multiplexer 720 may select one of the first pulse signal PS1, the second pulse signal PS2, and the third pulse signal PS3 based on a selection signal SEL, and output the selected signal as a selection pulse signal SPS.

For example, when the value of the selection signal SEL is ‘00’, the multiplexer 720 may output the first pulse signal PS1 as the selection pulse signal SPS. For example, when the value of the selection signal SEL is ‘01’, the multiplexer 720 may output the second pulse signal PS2 as the selection pulse signal SPS. For example, when the value of the selection signal SEL is ‘10’, the multiplexer 720 may output the third pulse signal PS3 as the selection pulse signal SPS. In other words, the selection pulse signal SPS may be one of the pulse signals of the first pulse signal PS1, the second pulse signal PS2, and the third pulse signal PS3.

The switch 730 may operate based on the selection pulse signal SPS. For example, when the selection pulse signal SPS has a logic high level, the switch 730 may be closed, and when the selection pulse signal SPS has a logic low level, the switch 730 may be opened.

The capacitor 740 may be connected between the switch 730 and a ground voltage GND. For example, when the switch 730 is closed, the capacitor 740 may be charged by the current source CUR_S, and accordingly, a voltage level of an input voltage IV may increase. For example, the input voltage IV may be generated based on the switch 730 and the capacitor 740.

The comparator 750 may output a comparison result signal CRS based on the input voltage IV and a threshold voltage V_TH. For example, the comparator 750 may output a signal having a higher voltage level among the input voltage IV and the threshold voltage V_TH as the comparison result signal CRS. For example, when the voltage level of the input voltage IV is higher than the voltage level of the threshold voltage V_TH, the comparator 750 may output the input voltage IV as the comparison result signal CRS. For example, when the voltage level of the threshold voltage V_TH is higher than the voltage level of the input voltage IV, the comparator 750 may output the threshold voltage V_TH as the comparison result signal CRS.

The counter circuit 760 may estimate the resolution time T1, which is the time corresponding to the first resolution, based on the comparison result signal CRS and a counter clock signal CLK_C, and output the resolution time T1. For example, the counter clock signal CLK_C may be the first pulse signal PS1, and the counter circuit 760 may operate based on the first pulse signal PS1.

For example, the counter circuit 760 may count the number of rising edges of the counter clock signal CLK_C by increasing the number by one at each rising edge of the counter clock signal CLK_C. For example, when the comparator 750 outputs the input voltage IV as the comparison result signal CRS, the counter circuit 760 may store the number of rising edges of the counter clock signal CLK_C. In other words, when the voltage level of the input voltage IV is higher than the voltage level of the threshold voltage V_TH, the counter circuit 760 may store the number of rising edges of the counter clock signal CLK_C.

For example, when the selection pulse signal SPS is the first pulse signal PS1, the counter circuit 760 may store the number of rising edges of the counter clock signal CLK_C at the time when the comparator 750 outputs the input voltage IV as the comparison result signal CRS. For example, when the selection pulse signal SPS is the first pulse signal PS1, the number of rising edges of the stored counter clock signal CLK_C may be referred to as N1.

For example, similarly to the above, when the selection pulse signal SPS is the second pulse signal PS2, the counter circuit 760 may store the number of rising edges of the counter clock signal CLK_C at the time when the comparator 750 outputs the input voltage IV as the comparison result signal CRS. In this case, the stored number of rising edges of the counter clock signal CLK_C may be referred to as N2.

For example, similarly to the above, when the selection pulse signal SPS is the third pulse signal PS3, the counter circuit 760 may store the number of rising edges of the counter clock signal CLK_C at the time when the comparator 750 outputs the input voltage IV as the comparison result signal CRS. In this case, the stored number of rising edges of the counter clock signal CLK_C may be referred to as N3.

For example, if the pulse width of the first pulse signal PS1 is P1, the pulse width of the second pulse signal PS2 is P2, and the pulse width of the third pulse signal PS3 is P3, the counter circuit 760 may estimate the resolution time T1 as shown in [Equation 1].

$$14 * P 3 * N 3 = 14 * P 2 * N 2 = P 1 * N 1 \qquad [ Equation 1 ]$$

$$T 1 = P 3 - P 2 = ( P 1 / 14 ) * \{ ( N 1 / N 3 ) - ( N 1 / N 2 ) \}$$

For example, the counter circuit 760 may output the resolution time T1 according to the [Equation 1].

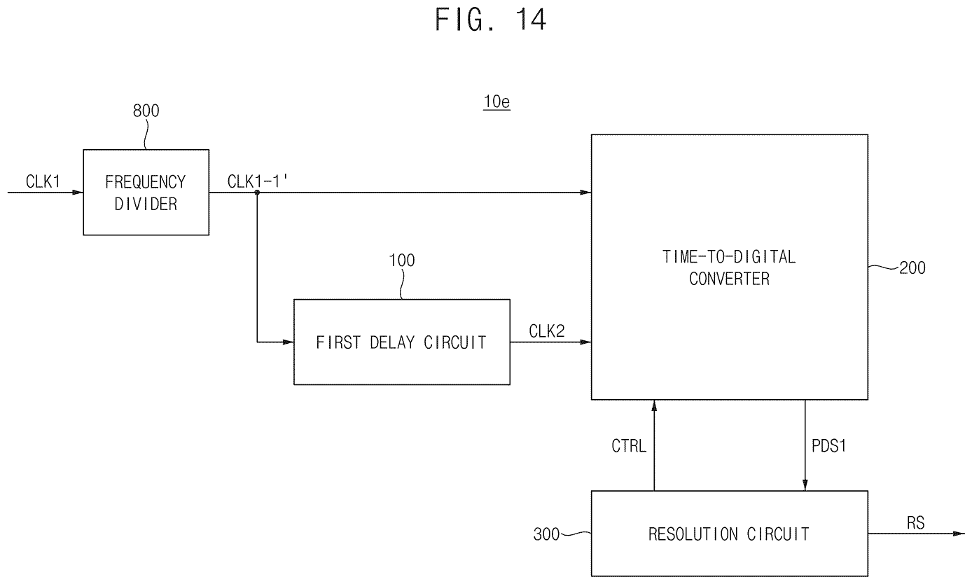

FIG. 14 is a block diagram illustrating an example of a jitter measurement circuit.

Referring to FIG. 14, a jitter measurement circuit 10e may further include a frequency divider 800 compared to the jitter measurement circuit 10 of FIG. 1. Hereinafter, the descriptions repeated with or overlapping with descriptions of FIG. 1 will be omitted in the interest of brevity.

The frequency divider 800 may output divide a frequency of the first clock signal CLK1 to output a first-first clock signal CLK1-1′. For example, the frequency divider 800 may divide the frequency of the first clock signal CLK1 such that the jitter measurement circuit 10e operates at a frequency equal to or less than 1GHz.

For example, the first delay circuit 100 may output the second clock signal CLK2 which is delayed from the first-first clock signal CLK1-1′ based on the first-first clock signal CLK1-1', and the time-to-digital converter 200 may output the plurality of first phase detection signals PDS1 based on the first-first clock signal CLK1-1', the second clock signal CLK2, and the control signal CTRL.

In some implementations, the jitter measurement circuit may include the first delay circuit (e.g., 100 in FIG. 1), the time-to-digital converter (e.g., 200 in FIG. 1), the resolution circuit (e.g., 300 in FIG. 1), the chopper (e.g., 400 in FIG. 7), the second delay circuit (e.g., 500 in FIG. 9), the signal converter (e.g., 600 in FIG. 11), the resolution estimation circuit (e.g., 700 in FIG. 12), and the frequency divider (e.g., 800 in FIG. 14).

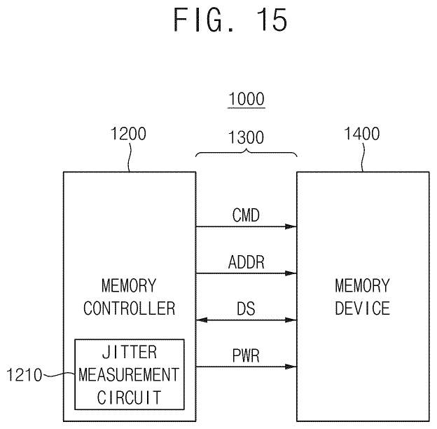

FIG. 15 is a block diagram illustrating an example of a memory system.

Referring to FIG. 15, a memory system 1000 includes a memory controller 1200 and a memory device 1400. The memory system 1000 may further include a plurality of signal lines 1300 that electrically connect the memory controller 1200 with the memory device 1400.

The memory device 1400 is controlled by the memory controller 1200. For example, based on requests from a host, the memory controller 1200 may store (e.g., write or program) data into the memory device 1400, or may retrieve (e.g., read or sense) data from the memory device 1400.

The memory controller 1200 may include a jitter measurement circuit 1210. By determining the resolution depending on the level of the jitter, the jitter measurement circuit 1210 may measure the jitter precisely when the jitter is low, and may expand the jitter measurement range when the jitter is high, and thus the jitter measurement circuit 1210 have a flexibility in the jitter measurement.

The plurality of signal lines 1300 may include command lines, address lines, data input/output (I/O) lines and power lines. The memory controller 1200 may transmit a command CMD, and an address ADDR to the memory device 1400 via the command lines and the address lines, may exchange a data signal DS with the memory device 1400 via the data I/O lines, and may transmit a power supply voltage PWR to the memory device 1400 via the power lines. Although not illustrated in detail, the plurality of signal lines 1300 may further include data strobe signal (DQS) lines for transmitting a DQS signal.

The example implementations may be applied to various electronic devices and systems that include the jitter measurement circuit. For example, the example implementations may be applied to systems such as a personal computer (PC), a server computer, a data center, a workstation, a mobile phone, a smart phone, a tablet computer, a laptop computer, a personal digital assistant (PDA), a portable multimedia player (PMP), a digital camera, a portable game console, a music player, a camcorder, a video player, a navigation device, a wearable device, an internet of things (IoT) device, an internet of everything (IoE) device, an e-book reader, a virtual reality (VR) device, an augmented reality (AR) device, a robotic device, a drone, etc.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The foregoing is illustrative of example implementations and is not to be construed as limiting thereof. Although some example implementations have been described, those skilled in the art will readily appreciate that many modifications are possible in the example implementations without materially departing from the novel teachings and advantages of the example implementations. Accordingly, all such modifications are intended to be included within the scope of the example implementations as defined in the claims. Therefore, it is to be understood that the foregoing is illustrative of various example implementations and is not to be construed as limited to the specific example implementations disclosed, and that modifications to the disclosed example implementations, as well as other example implementations, are intended to be included within the scope of the appended claims.

What is claimed is:

1. A jitter measurement circuit comprising:
a first delay circuit configured to, based on a first clock signal, output a second clock signal, the second clock signal being delayed from the first clock signal;
a time-to-digital converter including a plurality of first delay cells, a plurality of second delay cells, and a plurality of first phase detectors, the plurality of first delay cells being configured to delay the first clock signal, the plurality of second delay cells being configured to delay the second clock signal, the plurality of first phase detectors being connected between the plurality of first delay cells and the plurality of second delay cells, and the time-to-digital converter being configured to output a plurality of first phase detection signals based on the first clock signal, the second clock signal, and a control signal; and
a resolution circuit configured to
output the control signal to control an amount of delay of the first clock signal,
determine, based on the plurality of first phase detection signals, a resolution of the time-to-digital converter as a first resolution, and
output a result signal corresponding to a level of a jitter of the first clock signal, the resolution of the time-to-digital converter being configured to change depending on the level of the jitter.

2. The jitter measurement circuit of claim 1, wherein the plurality of first phase detectors are configured to output the plurality of first phase detection signals based on a phase difference between a plurality of first delay clock signals and a plurality of second delay clock signals,
wherein the plurality of first delay clock signals are generated based on passing the first clock signal through the plurality of first delay cells, and
wherein the plurality of second delay clock signals are generated based on passing the second clock signal through the plurality of second delay cells.

3. The jitter measurement circuit of claim 1, wherein the resolution circuit is configured to determine the first resolution based on a last first phase detection signal among the plurality of first phase detection signals, and
wherein the last first phase detection signal is generated based on a phase difference between a last first delay clock signal and a last second delay clock signal, the last first delay clock signal being generated based on passing the first clock signal through the plurality of first delay cells, and the last second delay clock signal being generated based on passing the second clock signal through the plurality of second delay cells.

4. The jitter measurement circuit of claim 1, wherein the first resolution is proportional to a value of the control signal.

5. The jitter measurement circuit of claim 1, wherein an amount of delay of the second clock signal is maintained regardless of the control signal, and the amount of delay of the first clock signal is changed by the control signal.

6. The jitter measurement circuit of claim 1, wherein the first delay circuit includes:
a third delay cell configured to output the second clock signal based on the first clock signal and a delay calibration signal;
a second phase detector configured to output a second phase detection signal based on a phase difference between the first clock signal and the second clock signal; and
a delay calibration circuit configured to output the delay calibration signal based on the second phase detection signal, the delay calibration signal being configured to calibrate an amount of delay of the second clock signal.

7. The jitter measurement circuit of claim 6, comprising:
a chopper configured to output a third clock signal and a fourth clock signal by maintaining or changing a first path of the first clock signal and a second path of the second clock signal based on the first clock signal, the second clock signal, and the second phase detection signal,
wherein the time-to-digital converter is configured to output the plurality of first phase detection signals based on the third clock signal, the fourth clock signal, and the control signal.

8. The jitter measurement circuit of claim 7, wherein the chopper is configured to, based on a phase of the first clock signal leading a phase of the second clock signal,
output, as the third clock signal, the first clock signal, and
output, as the fourth clock signal, the second clock signal.

9. The jitter measurement circuit of claim 7, wherein the chopper is configured to, based on a phase of the second clock signal leading a phase of the first clock signal,
output, as the third clock signal, the second clock signal, and
output, as the fourth clock signal, the first clock signal.

10. The jitter measurement circuit of claim 7, comprising:
a second delay circuit configured to calibrate, based on the third clock signal, the fourth clock signal, and the second phase detection signal, a chopper offset occurring in one of the third clock signal and the fourth clock signal, the third clock signal and the fourth clock signal being received from the chopper.

11. The jitter measurement circuit of claim 10, wherein the second delay circuit includes:
a fourth delay cell configured to output a third-first clock signal based on a chopper offset calibration signal and the third clock signal, the chopper offset calibration signal being configured to calibrate the chopper offset, and the third clock signal being received from the chopper;
a third phase detector configured to output a third phase detection signal based on a phase difference between the fourth clock signal received from the chopper and the third-first clock signal; and
a chopper offset calibration circuit configured to output the chopper offset calibration signal based on the second phase detection signal and the third phase detection signal, and
wherein the time-to-digital converter is configured to output the plurality of first phase detection signals based on the third-first clock signal, the fourth clock signal, and the control signal.

12. The jitter measurement circuit of claim 10, wherein the second delay circuit includes:
a fourth delay cell configured to output a fourth-first clock signal based on a chopper offset calibration signal and the fourth clock signal, the chopper offset calibration signal being configured to calibrate the chopper offset, and the fourth clock signal being received from the chopper;
a third phase detector configured to output a third phase detection signal based on a phase difference between the third clock signal received from the chopper and the fourth-first clock signal; and
a chopper offset calibration circuit configured to output the chopper offset calibration signal based on the second phase detection signal and the third phase detection signal, and
wherein the time-to-digital converter is configured to output the plurality of first phase detection signals based on the third clock signal, the fourth-first clock signal, and the control signal.

13. The jitter measurement circuit of claim 6, comprising:
a signal converter configured to output a jitter measurement signal based on the result signal and the second phase detection signal, the jitter measurement signal representing the level of the jitter.

14. The jitter measurement circuit of claim 2, comprising:
a resolution estimation circuit configured to estimate a time corresponding to the first resolution based on two first delay clock signals among the plurality of first delay clock signals.

15. The jitter measurement circuit of claim 14, wherein the resolution estimation circuit includes:
a signal generator configured to output a plurality of pulse signals based on the two first delay clock signals;
a multiplexer configured to output a selection pulse signal from the plurality of pulse signals;
a switch configured to operate based on the selection pulse signal;
a capacitor connected between the switch and a ground voltage;
a comparator configured to output a comparison result signal based on an input signal and a threshold voltage, the input signal being generated based on the switch and the capacitor; and
a counter circuit configured to estimate the time corresponding to the first resolution based on the comparison result signal and a counter clock signal.

16. The jitter measurement circuit of claim 1, comprising:
a frequency divider configured to output a first-first clock signal based on dividing a frequency of the first clock signal, and
wherein the first delay circuit is configured to output the second clock signal based on the first-first clock signal, and
wherein the time-to-digital converter is configured to output the plurality of first phase detection signals based on the first-first clock signal, the second clock signal, and the control signal.

17. A method of measuring a jitter, comprising:
outputting, based on a first clock signal, a second clock signal, the second clock signal being delayed from the first clock signal;
delaying, by a plurality of first delay cells, the first clock signal based on a control signal;
delaying, by a plurality of second delay cells, the second clock signal;
determining, as a first resolution, a resolution of a time-to-digital converter based on a phase difference between a plurality of first delay clock signals and a plurality of second delay clock signals, the plurality of first delay clock signals being generated based on passing the first clock signal through the plurality of first delay cells, the plurality of second delay clock signals being generated based on passing the second clock signal through the plurality of second delay cells, and the resolution of the time-to-digital converter being configured to change depending on a level of the jitter of the first clock signal; and
outputting, based on the first resolution, a result signal corresponding to the level of the jitter.

18. The method of claim 17, wherein determining, as the first resolution, the resolution of the time-to-digital converter includes:
initializing a value of the control signal and a value of a count signal, the count signal counting a number of repetitions of an operation;
determining a number of values having a first logic level among a plurality of values included in a last first phase detection signal among a plurality of first phase detection signals;
based on the number of the values having the first logic level being greater than a reference number, increasing the value of the control signal and initializing the value of the count signal;
based on the number of the values having the first logic level being less than or equal to the reference number, increasing the value of the count signal;
based on the value of the count signal being greater than or equal to a first value, selecting the resolution of the time-to-digital converter as the first resolution, and
wherein the last first phase detection signal is generated based on a phase difference between a last first delay clock signal and a last second delay clock signal, the last first delay clock signal is generated based on passing the first clock signal through the plurality of first delay cells, and the last second delay clock signal is generated based on passing the second clock signal through the plurality of second delay cells.

19. The method of claim 18, wherein the first resolution is proportional to the value of the control signal.

20. A jitter measurement circuit comprising:
a time-to-digital converter including a plurality of first delay cells, a plurality of second delay cells, and a plurality of first phase detectors, the plurality of first delay cells being configured to output a plurality of first delay clock signals by delaying a first clock signal based on a control signal, the plurality of second delay cells being configured to output a plurality of second delay clock signals by delaying a second clock signal, the second clock signal being delayed from the first clock signal, the plurality of first phase detectors being connected between the plurality of first delay cells and the plurality of second delay cells, and the plurality of first phase detectors being configured to output a plurality of first phase detection signals based on a phase difference between the plurality of first delay clock signals and the plurality of second delay clock signals;
a first delay circuit configured to output the second clock signal based on the first clock signal, the first delay circuit including a second phase detector configured to output a second phase detection signal based on a phase difference between the first clock signal and the second clock signal;
a resolution circuit configured to
output the control signal configured to control an amount of delay of the first clock signal,
determine, based on the plurality of first phase detection signals, a resolution of the time-to-digital converter as a first resolution, and
output a result signal corresponding to a level of a jitter of the first clock signal, the resolution of the time-to-digital converter being configured to change depending on the level of the jitter;
a chopper configured to maintain or change a first path of the first clock signal and a second path of the second clock signal based on the first clock signal, the second clock signal, and the second phase detection signal;
a signal converter configured to output a jitter measurement signal based on the result signal and the second phase detection signal, the jitter measurement signal representing the level of the jitter; and
a resolution estimation circuit configured to estimate, based on two first delay clock signals among the plurality of first delay clock signals, a time corresponding to the first resolution.
